(19) United States
(12) Patent Application Publication
(10) Pub. No.: US 2016/0190056 A1
(43) Pub. Date: Jun. 30, 2016

(54) INTEGRATED CIRCUIT PACKAGING SYSTEM WITH PACKAGE-ON-PACKAGE MECHANISM AND METHOD OF MANUFACTURE THEREOF

(71) Applicants: SooSan Park, Seoul (KR); HeeJo Chi, Yeoju-gun (KR); Byung Tai Do, Singapore (SG)

(72) Inventors: SooSan Park, Seoul (KR); HeeJo Chi, Yeoju-gun (KR); Byung Tai Do, Singapore (SG)

(21) Appl. No.: 14/980,292

(22) Filed: Dec. 28, 2015

Related U.S. Application Data
(60) Provisional application No. 62/097,248, filed on Dec. 29, 2014.

(51) Int. Cl. H01L 23/498; H01L 23/00; H01L 21/48

(52) U.S. Cl. CPC H01L 23/49833; H01L 23/49827; H01L 23/49838; H01L 23/49816; H01L 21/486; H01L 24/83; H01L 24/32; H01L 21/4853; H01L 2224/838; H01L 2924/15747; H01L 2224/32225; H01L 2924/14

(57) ABSTRACT

An integrated circuit packaging system, and a method of manufacture thereof, including: a substrate; a metal core interconnect attached to the substrate; an upper connection joint attached above and to the metal core interconnect; and an interposer attached to the upper connection joint.

### CROSS-REFERENCE TO RELATED APPLICATION(S)

This application claims the benefit of U.S. Provisional Patent Application Ser. No. 62/097,248 filed Dec. 29, 2014, and the subject matter thereof is incorporated herein by reference thereto.

### p TECHNICAL FIELD

The present invention relates generally to an integrated circuit packaging system, and more particularly to a system for facilitating a package-on-package structure.

### BACKGROUND ART

The rapidly growing market for portable electronics devices, e.g. cellular phones, laptop computers, and other mobile devices, is an integral facet of modern life. The multitude of portable devices represents one of the largest potential market opportunities for next generation packaging. These devices have unique attributes that have significant impacts on manufacturing integration, in that they must be generally small, lightweight, and rich in functionality and they must be produced in high volumes at relatively low cost.

As an extension of the semiconductor industry, the electronics packaging industry has witnessed ever-increasing commercial competitive pressures, along with growing consumer expectations and the diminishing opportunities for meaningful product differentiation in the marketplace.

Packaging, materials engineering, and development are at the very core of these next generation electronics insertion strategies outlined in road maps for development of next generation products. Future electronic systems may be more intelligent, have higher density, use less power, operate at higher speed, and may include mixed technology devices and assembly structures at lower cost than today.

The envelope of technical capability of next level interconnect assemblies are not yet known, and no clear cost effective technology has yet been identified. Beyond the performance requirements of next generation devices, the industry now demands that cost be a primary product differentiator in an attempt to meet profit goals.

As these packaging systems evolve to incorporate more components with varied environmental needs, the pressure to push the technological envelope becomes increasingly challenging. More significantly, with the ever-increasing complexity, the potential risk of error increases greatly during manufacture.

Among the problems being encountered with the shrinking of packaging systems is the decreasing space available for components. As distances between interconnects decreases, problems such as solder bridging and too much contact with sensitive components become more important.

In view of the ever-increasing commercial competitive pressures, along with growing consumer expectations and the diminishing opportunities for meaningful product differentiation in the marketplace, it is critical that answers be found for these problems. Additionally, the need to reduce costs, reduce production time, improve efficiencies and performance, and meet competitive pressures, adds an even greater urgency to the critical necessity for finding answers to these problems.

Thus, a need remains for smaller footprints and more robust packages and methods for manufacture. Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit packaging system that includes depositing an upper connection joint on an interposer; attaching a metal core interconnect to the upper connection joint; and attaching the metal core interconnect and the interposer to a substrate.

The present invention provides an integrated circuit packaging system that includes a substrate; a metal core interconnect attached to the substrate; an upper connection joint attached above and to the metal core interconnect; and an interposer attached to the upper connection joint.

Certain embodiments of the invention have other steps or elements in addition to or in place of those mentioned above. The steps or element will become apparent to those skilled in the art from a reading of the following detailed description when taken with reference to the accompanying drawings.

### BRIEF DESCRIPTION OF THE DRAWINGS

FIG. 1 is a bottom view of an integrated circuit packaging system with package-on-package mechanism in a first embodiment of the present invention.

FIG. 2 is a cross-sectional view of the integrated circuit packaging system along the section line 2-2 of FIG. 1.

FIG. 3 is a detailed exemplary view of a portion of the integrated circuit packaging system as taken from the right side of the cross-sectional view of FIG. 2.

FIG. 4 is a cross-sectional view of the integrated circuit packaging system of FIG. 2 in an interposer mounting phase of manufacture.

FIG. 5 is a flow chart of a method of manufacture of an integrated circuit packaging system in a further embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings for ease of description generally show similar orientations, this depiction in the FIGs. is arbitrary for the most part. Generally, the invention can be operated in any orientation.

The same numbers are used in all the drawing FIGs. to relate to the same elements. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the active surface of the integrated circuit die, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures. The term “on” means that there is direct contact between elements. The term “directly on” means that there is direct contact between one element and another element without an intervening element.

The term “active side” refers to a side of a die, a module, a package, or an electronic structure having active circuitry fabricated thereon or having elements for connection to the active circuitry within the die, the module, the package, or the electronic structure.

The term “processing” as used herein includes deposition of material or photoresist, patterning, exposure, development, etching, cleaning, and/or removal of the material or photoresist as required in forming a described structure.

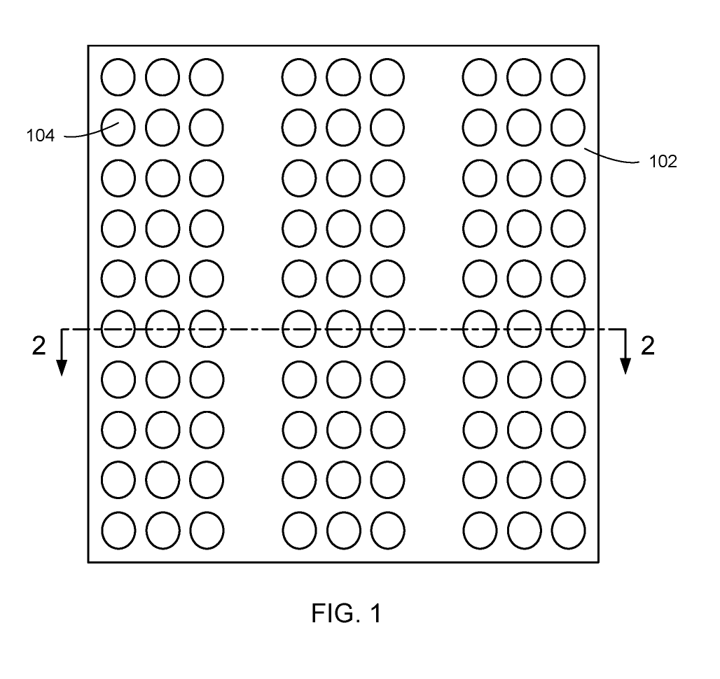

Referring now to FIG. 1, therein is shown a bottom view of an integrated circuit packaging system 100 with package-on-package mechanism in a first embodiment of the present invention. In this view can be seen a substrate 102 and external interconnects 104.

The substrate 102 is defined as a structure containing conductive traces and contacts. For example, the substrate 102 can be a laminate material, a metallic material, a ceramic material, or a combination thereof. The substrate 102 can have the external interconnects 104 on contact pads for connection to other components or next level systems.

The external interconnects 104, such as solder balls, can function to electrically connect components internal to the integrated circuit packaging system 100 to the outside. The external interconnects 104 can be arranged in an array as shown or can be arranged in a staggered, regular, or irregular array, for example. The external interconnects 104 can also provide a path to ground.

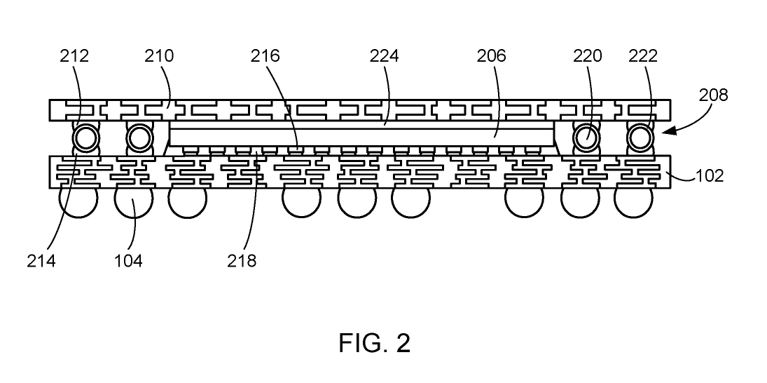

Referring now to FIG. 2, therein is shown a cross-sectional view of the integrated circuit packaging system 100 along the section line 2-2 of FIG. 1. The cross-sectional view shows the substrate 102, an integrated circuit die 206, metal core interconnects 208, an interposer 210, and the external interconnects 104.

The integrated circuit die 206, such as a flip chip, can be mounted on the substrate 102 opposite the external interconnects 104. In this example, an underfill 218 is between the integrated circuit die 206 and the substrate 102. The underfill 218 surrounds internal interconnects 216 which connect the integrated circuit die 206 to the substrate 102. An interposer adhesive 224 connects the integrated circuit die 206 to the interposer 210.

Surrounding the integrated circuit die 206 in a lateral direction are the metal core interconnects 208, which are also attached to the substrate 102. The metal core interconnects 208 can be formed from various materials. For example, the metal core interconnects 208 can be made from a solid metal core 220, such as a copper or copper alloy core, covered in an anti-oxide layer 222. The anti-oxide layer 222 can be oxidized copper, palladium, gold, an organic solderability preservative (OSP), nickel, or some combination thereof, for example.

The metal core interconnects 208 are attached to the substrate 102 and the interposer 210 with a lower connection joint 214 and an upper connection joint 212, respectively. The lower connection joint 214 and the upper connection joint 212 can be formed from a conductive paste such as solder paste, an anisotropic conductive paste (ACP), or an anisotropic conductive film (ACF).

It has been discovered that the use of the lower connection joint 214 and the upper connection joint 212 in conjunction with the metal core interconnects 208 provides a robust and reliable package without requiring capital-intensive replacement of equipment. For example, as the size of packages decreases, the interposer 210 will become thinner and thinner. Due to this, warpage of the interposer 210 is common during assembly and any reflow step. This warpage can lead to open connections or solder bridging causing shorts. To prevent this, a jig or other mechanism can be used to hold the interposer 210 in place during manufacturing; regular solder balls as a connection may not stand up to the pressure and this can lead to damage of the integrated circuit die 206. However, the metal core interconnects 208 can withstand the pressure from the jig and can prevent damage to the integrated circuit die 206.

It has also been discovered that the use of solder paste, ACP, or ACF for the lower connection joint 214 and the upper connection joint 212 can enable the creation of a smaller package. Because the lower connection joint 214 and the upper connection joint 212 can be formed as anisotropic solder joints which only contact the metal core interconnects 208 on the top or bottom, less volume of material is required for connection. This results in the ability to achieve a finer pitch between the metal core interconnects 208 without the danger of solder bridging. This allows for the creation of smaller packages with the same level of reliability as the older, larger packages. For example, this can provide for a metal core interconnect pitch of 300 micrometers or lower.

It has further been discovered that the use of solder paste, ACP, or ACF or the lower connection joint 214 and the upper connection joint 212 together with the metal core interconnects 208 provides a reliable and compact package with no increase in cost. For example, not only do the metal core interconnects 208 provides support for the interposer 210 to protect the integrated circuit die 206 from damage, the lower connection joint 214 and the upper connection joint 212 can function to hold the metal core interconnects 208 in place, meaning that no modifications to a standard substrate or interposer are required; it becomes unnecessary to have a thick solder resist layer on the substrate 102 or a cavity in the interposer 210 in order to secure solder connections that did not use the connection joint score the metal core interconnects 208. Solder paste, ACP, or ACF all have stronger adhesive properties then simply using solder on a pad.

Thus, it has been discovered that the integrated circuit packaging system 100 and method of manufacture thereof furnish important and heretofore unknown and unavailable solutions, capabilities, and functional aspects for manufacturing reliable and compact integrated circuit packages.

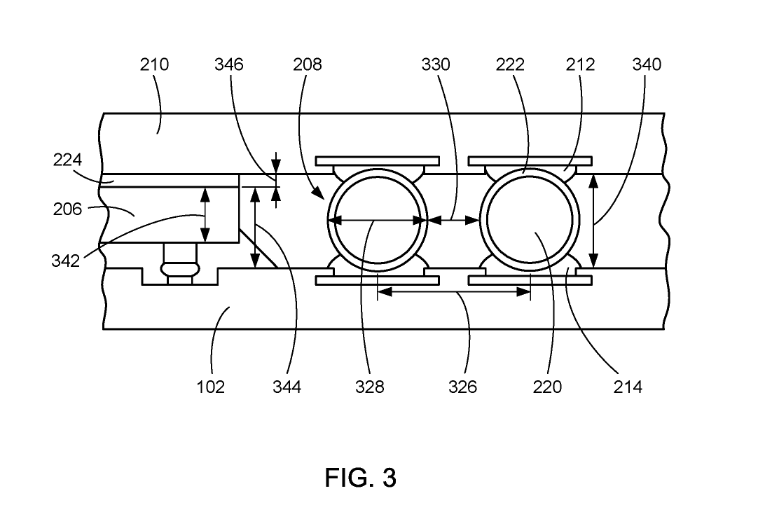

Referring now to FIG. 3, therein is shown a detailed exemplary view of a portion of the integrated circuit packaging system 100 as taken from the right side of the cross-sectional view of FIG. 2. The wavy lines on the sides of the figure indicate that only a portion is shown. The detailed exemplary view is for example only, and is only one illustrative example of the structure of the substrate 102 and the interposer 210. Certain details such as the external interconnects 104 of FIG. 1 and internal redistribution layers of the substrate 102 and the interposer 210 are omitted for clarity.

Visible in this figure is a closer view at the solid metal core 220 and the anti-oxide layer 222 of the metal core interconnects 208. The metal core interconnects 208 are held between the substrate 102 and the interposer 210 by the lower connection joint 214 and the upper connection joint 212, respectively. A portion of the integrated circuit die 206 is attached to the interposer 210 by the interposer adhesive 224.

Indicated by the various lines and arrows within the figure are important dimensions. These dimensions include an interconnect pitch 326, a metal core interconnect diameter 328, an interconnect gap 330, a substrate-interposer gap 340, a die thickness 342, a die height 344, and an interposer adhesive height 346. The various dimensions vary based on the die thickness 342 because the substrate-interposer gap 340 must be large enough to protect the integrated circuit die 206 from damage. The substrate-interposer gap 340 is dependent on the metal core interconnect diameter 328.

For example, the metal core interconnect diameter 328 can range from 200 μm to 150 μm. This corresponds with the die thickness 342 ranging from 100 μm to 70 μm. The interconnect gap 330 can range from 100 μm to 50 μm. The interconnect pitch 326 can range from 300 μm to 200 μm (0.3 mm to 0.2 mm). Similarly, the die height 344 can range from 150 μm to 100 μm. This corresponds with a range for the interposer adhesive height 346 of 70 μm to 30 μm. All numbers are for example only. It is understood that the metal core interconnect diameter 328 can be far lower than the examples given and can be as low as 10 μm if the die thickness 342 can be made low enough to accommodate this size.

It is been discovered that the use of solder pastes, ACP, or ACF for the lower connection joint 214 and the upper connection joint 212 can allow for smaller packages through finer pitch. Because of the adhesion of the lower connection joint 214 and the upper connection joint 212 to the metal core interconnects 208, along with careful volume control, it is possible to lower the interconnect pitch 326 and form a package having finer pitch between the metal core interconnects 208, which allows for a smaller package size overall. For example, the volume of the either the lower connection joint 214 or the upper connection joint 212 can be from 3% to 50% of the volume of each of the metal core interconnects 208. Additionally, it has been found that adhesion is properly balanced against the need to avoid solder bridging when the volume of the lower connection joint 214 or the upper connection joint 212 is roughly 18% to 27% of the volume of each of the metal core interconnects 208.

It has also been discovered that the smaller values of the interconnect pitch 326 that are possible reduces resistance and power loss within the integrated circuit packaging system 100. Because the distance any given signal must travel through the package is reduced due to smaller value for the interconnect pitch 326 along with corresponding smaller values for other dimensions, there will be less signal loss or degradation due to distance.

It has been discovered that as long as the metal core interconnect diameter 328 is larger than the die thickness 342, no additional encapsulation is necessary, which can save on manufacturing complexity and cost while also increasing reliability. Once the metal core interconnect diameter 328 is large enough, there is very little danger of damage to the integrated circuit die 206 from the interposer 210. Thus, the metal core interconnects 208 can protect the integrated circuit die 206 from damage without the need for an encapsulation step which could potentially damage the integrated circuit die 206 or prevent proper heat dissipation from the integrated circuit die 206 during operation. Better airflow over the integrated circuit die 206 is assured if there is no additional encapsulation required.

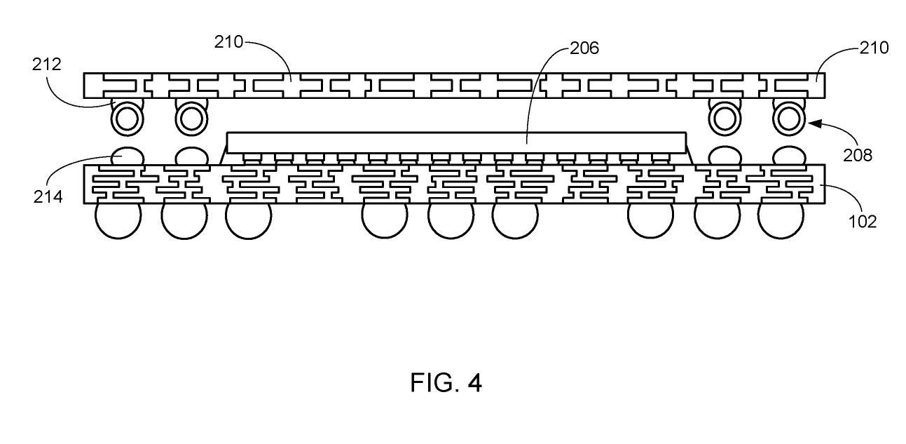

Referring now to FIG. 4, therein is shown a cross-sectional view of the integrated circuit packaging system 100 of FIG. 2 in an interposer mounting phase of manufacture. In this example process, there are two separate structures formed first, and shown in the figure is the step wherein these two structures are combined together. The two structures can be formed in any order.

The upper connection joint 212 can be printed or deposited on contact pads of the interposer 210. This can be followed by attaching the metal core interconnects 208 to the upper connection joint 212 on the interposer 210. A reflow step can solidify the connection between the interposer 210 and the metal core interconnects 208. This also allows the metal core interconnects 208 to self-align on the upper connection joint 212. For illustrative purposes, the interposer 210 is used in this example, but it is understood that any substrate or package can be used.

Separately, for example, the integrated circuit die 206 can be attached to the substrate 102. Additionally, the lower connection joint 214 can be printed or deposited on contact pads of the substrate 102 around the integrated circuit die 206. At this point, the interposer 210 can be mounted on top of the substrate 102 by positioning the metal core interconnects 208 (still attached to the interposer 210, as can be seen in the figure) on the lower connection joint 214. This can be followed by a second reflow step to finish connecting the metal core interconnects 208 to both the lower connection joint 214 and the upper connection joint 212. The interposer adhesive 224 of FIG. 2 can also be used as necessary, though it is not shown in this figure.

It has been discovered that attaching the metal core interconnects 208 to the interposer 210 before attaching the metal core interconnects 208 to the substrate 102 simplifies the manufacturing process and improves reliability and cost performance. At the first attach step where the metal core interconnects 208 are attached to the upper connection joint 212 followed by a reflow step, the metal core interconnects 208 self-align during the reflow step on the contact pads of the interposer 210. This removes the need for careful alignment of the interposer 210 over the substrate 102 if the metal core interconnects 208 were attached to the substrate 102 first, because self-alignment would not work. This simplifies manufacturing, saves time and money, and improves reliability due to the metal core interconnects 208 being properly aligned.

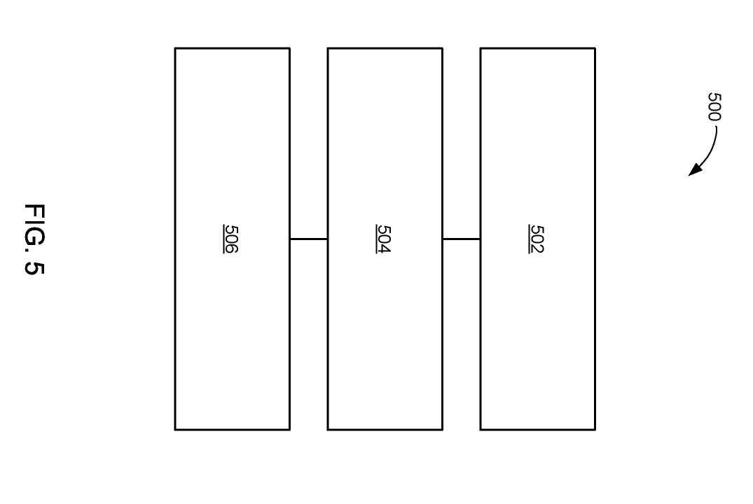

Referring now to FIG. 5, therein is shown a flow chart of a method 500 of manufacture of an integrated circuit packaging system in a further embodiment of the present invention. The method 500 includes: depositing an upper connection joint on an interposer in a block 502; attaching a metal core interconnect to the upper connection joint in a block 504; and attaching the metal core interconnect and the interposer to a substrate in a block 506.

The resulting method, process, apparatus, device, product, and/or system is straightforward, cost-effective, uncomplicated, highly versatile and effective, can be surprisingly and unobviously implemented by adapting known technologies, and are thus readily suited for efficiently and economically manufacturing integrated circuit packaging systems

Another important aspect of the present invention is that it valuably supports and services the historical trend of reducing costs, simplifying systems, and increasing performance.

These and other valuable aspects of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit packaging system comprising:
depositing an upper connection joint on an interposer;
attaching a metal core interconnect to the upper connection joint; and
attaching the metal core interconnect and the interposer to a substrate.

2. The method as claimed in claim 1 further comprising mounting an integrated circuit die to the substrate.

3. The method as claimed in claim 1 further comprising heating the metal core interconnect, the interposer, and the upper connection joint for reflowing the upper connection joint.

4. The method as claimed in claim 1 further comprising:
depositing a lower connection joint on the substrate; and
attaching the metal core interconnect and the interposer to the lower connection joint.

5. The method as claimed in claim 1 wherein attaching the metal core interconnect includes attaching a solid metal core covered in an anti-oxide layer.

6. A method of manufacture of an integrated circuit packaging system comprising:
depositing an upper connection joint on an interposer;
attaching a metal core interconnect to the upper connection joint;
heating the metal core interconnect, the interposer, and the upper connection joint for reflowing the upper connection joint;
mounting an integrated circuit die to a substrate; and
attaching the metal core interconnect and the interposer to the substrate.

7. The method as claimed in claim 6 further comprising heating the metal core interconnect, the lower connection joint, the upper connection joint, the interposer, and the substrate for reflowing the lower connection joint.

8. The method as claimed in claim 6 wherein depositing the upper connection joint includes depositing a solder paste.

9. The method as claimed in claim 6 wherein depositing the upper connection joint includes depositing an anisotropic conductive paste.

10. The method as claimed in claim 6 wherein depositing the upper connection joint includes depositing an anisotropic conductive film.

11. An integrated circuit packaging system comprising:
a substrate;
a metal core interconnect attached to the substrate;
an upper connection joint attached above and to the metal core interconnect; and
an interposer attached to the upper connection joint.

12. The system as claimed in claim 11 further comprising an integrated circuit die mounted on the substrate.

13. The system as claimed in claim 11 further comprising:
an integrated circuit die mounted on the substrate; and
an interposer adhesive on and between the integrated circuit die and the interposer.

14. The system as claimed in claim 11 further comprising a lower connection joint between and on the substrate and the metal core interconnect.

15. The system as claimed in claim 11 wherein the metal core interconnect includes a solid metal core covered in an anti-oxide layer.

16. The system as claimed in claim 11 further comprising:
an integrated circuit die mounted on the substrate;
an interposer adhesive on and between the integrated circuit die and the interposer; and
a lower connection joint between and on the substrate and the metal core interconnect.

17. The system as claimed in claim 16 wherein the metal core interconnect includes a solid copper or copper alloy core.

18. The system as claimed in claim 16 wherein the upper connection joint is a solder paste.

19. The system as claimed in claim 16 wherein the upper connection joint is an anisotropic conductive paste.

20. The system as claimed in claim 16 wherein the upper connection joint is an anisotropic conductive film.
